(19) United States
(12) Patent Application Publication
(10) Pub. No.: US 2004/0086792 A1
(43) Pub. Date: May 6, 2004

(54) Lithographic mask for semiconductor devices with a polygonal-section etch window, in particular having a section of at least six sides

(76) Inventors: Carmelo Romeo, Vimercate (IT); Paolo Canestrari, Merate (IT); Antonio Fiorino, S. Giuliano M. (IT)

Correspondence Address: WOLF GREENFIELD & SACKS, PC, FEDERAL RESERVE PLAZA, 600 ATLANTIC AVENUE, BOSTON, MA, 02210-2211, US

(21) Appl. No.: 10/693,479

(22) Filed: Oct. 24, 2003

Related U.S. Application Data
(62) Division of application No. 09/632,031, filed on Aug. 2, 2000, now abandoned.

(30) Foreign Application Priority Data
Aug. 5, 1999 (IT) MI99A 001768

(51) Int. Cl. G03F 9/00

(52) U.S. Cl. 430/5

(57) ABSTRACT

Using an attenuated phase shifting mask (Att.PSM) with square-section etch window there is the advantage of permitting good resolution and simultaneously increasing the depth of focus and the exposure latitude (the range of energy), improving the lithographic process itself compared to the traditional masks, called binary. The Att.PSM masks introduce the problem of the side lobe effects which is solved with the present invention adopting a polygonal etch window with at least six sides, preferably with an octagonal shape.

### CROSS REFERENCE TO RELATED APPLICATIONS

This application is a divisional of U.S. application Ser. No. 09/632,031, filed Aug. 2, 2000 entitled LITHOGRAPHIC MASK FOR SEMICONDUCTOR DEVICES WITH A POLYGONAL-SECTION ETCH WINDOW, IN PARTICULAR HAVING A SECTION OF AT LEAST SIX SIDES, which is incorporated herein by reference in its entirety.

### BACKGROUND OF THE INVENTION

1. Field of the Invention

The present invention relates to a covering mask for semiconductor devices with a polygonal-section etch window, in particular having a section of at least six sides.

2. Discussion of the Related Art

Any integrated circuit is produced starting from a substrate in which an active zone is formed which uses the physical properties of the metal-oxide-semiconductor system and of the interconnection system, usually realized in aluminium alloy, to enable the integrated circuit to work.

The interconnection system and the active zone inter-communicate by means of contacts.

The contacts therefore have the purpose of connecting each cell of a device, in the case of memories, or each transistor, in the case of logic gates, with the interconnection lines. The number of contacts present in a device varies from several hundreds of thousands to some tens of millions which implies that the defectiveness of said contacts, intended as number of non-functioning contacts, is one of the main parameters for assessing the quality of the production process. The contacts must have an ohmic behavior at the variation of the applied voltage, that is the current measured must follow Ohm's law.

The continuous progress of technology, the market demand, and competition drive integrated semiconductor device manufacturers to produce electronic devices that are smaller and smaller with greater storage capacities. This clashes with the technological capacity to produce contacts having dimensions and operating capabilities that can meet all the technological parameters. In the latest generations of devices, the dimensions of the contacts have reached 0.2 μm. Such result can be obtained only thanks to an accurate control of all the phases of implementation of every single process level, such as the lithographic, etching and removal levels.

The process that defines the form and the dimension of the contacts is the lithographic process. This process produces the contacts on a photosensitive resin deposited on the wafer, by means of the exposition of a binary mask of chrome to a light source consisting of a lamp or a laser. This light passes through the quartz windows provided on said mask, also called a reticle, so that it is diffracted and focused by a series of projection lenses into the resist film, where the exposed zones are dissolved by a basic development.

The conventional mask consists of a quartz plate, which is a transparent means to the incident light, with a layer of chrome above, which is opaque to the incident light, on which said windows are defined, with a square section, in correspondence with the circuit pattern to be transferred on the silicon wafer, by means of the above-mentioned focusing system. This type of reticle defines the so-called binary mask and permits the printing of the contacts with the resolution of 0.2 μm, but the depth of focus obtained is insufficient to guarantee a stable contact formation process for industrial purposes.

Better performance for the depth of focus can be obtained through phase shifting masks (Phase Shifting Masks, PSM). Among the various masks of this type that have been developed, the one that has been found to be more popular is the attenuated phase shifting mask (Attenuated Phase Shifting Mask, Att. PSM). This particular type of mask, or reticle, uses a layer of partially transparent material capable of inducing a phase variation of 180° of the electric field of the incident wave instead of chrome. This type of mask, therefore, has the characteristic of being partially transparent in the zones corresponding to the dark zones of a binary mask, and in addition, in said zones the electric field is shifted by a material called “shifter”.

On the contrary to the classic masks, that is to the binary masks, where the transmittance (T) is null, in this case the transmittance is different from zero. The value of T is defined during the phase of construction of the mask by choosing the thickness of the shifter and the composition of the material, also in function of the wavelength used.

The use of this type of mask therefore improves the resolution of the contact and increases the depth of focus but it must be taken into consideration that there is also a presence of secondary peaks of transmission of the incident light through the shifter. When the intensity of the secondary peaks is not longer a very small portion of the incident light from the quartz window, we shall observe on the wafer new features, placed on the side of and external to the area that actually needs to be attacked, giving rise to what is indicated as the effect of the side lobes (“side lobe effect”).

This can bring several disadvantages such as, in the case of dense contacts, having the possibility of a short circuit or also the difficulty in carrying out the measurement of the contact dimension, which results in being blurred and therefore lower in quality.

With the use of an Att.PSM mask, consideration must be taken, therefore, of the side lobe effect that causes, during the development phase of the resist, at the end of the development process, in addition to the opening required, that is the one corresponding to the actual contact, also side openings near the zone of the contact itself.

In view of the state of the art described, an object of the present invention is to reduce the inconveniences caused by side lobes.

### SUMMARY OF THE INVENTION

According to the present invention, this and other objects are achieved by a lithographic mask for semiconductor devices including a first plate of transparent material and a layer placed over said first plate and of partially transparent material so as to cause a preset shifting of an incident luminous wave, wherein said layer has a polygonal-section etch window with at least six sides so that the side lobe effects are reduced.

The above-mentioned etch window has preferably an octagonal-shaped section.

It is also provided that the mask according to the invention has the etch window with a polygonal section so as to configure a basically circular shape.

Thanks to the present invention a mask can be produced with a polygonal-shaped etch window with at least six sides so that it is possible to reduce the undesired side lobe effects caused by the phase shifting masks, improving therefore the depth of focus connected to this particular technology.

### BRIEF DESCRIPTION OF THE DRAWINGS

The characteristics and the advantages of the present invention will be evident from the following detailed description of an embodiment thereof, illustrated as non-limiting example in the enclosed drawings, in which:

FIG. 1 schematically illustrates in section a binary mask according to the known art;

FIG. 2 shows an attenuated phase shifting mask according to the known art;

FIG. 3 illustrates a diffraction figure generated by a single square opening in a mask according to FIG. 2;

FIG. 4 shows a plurality of graphs of the transmission intensity in the case of Att.PSM-type masks according to the known art;

FIG. 5 illustrates a three-dimensional view of the side lobe effect in an Att.PSM-type mask according to the known art;

FIG. 6 shows a plan view of a portion of an Att.PSM-type mask according to the present invention;

FIG. 7 illustrates said mask according to the invention in section according to the VII-VII line of FIG. 6;

FIG. 8 shows a diffraction figure generated by a contact according to the invention; and

FIG. 9 illustrates a three-dimensional view of the side lobe effect in an Att.PSM-type mask according to the present invention.

### DETAILED DESCRIPTION

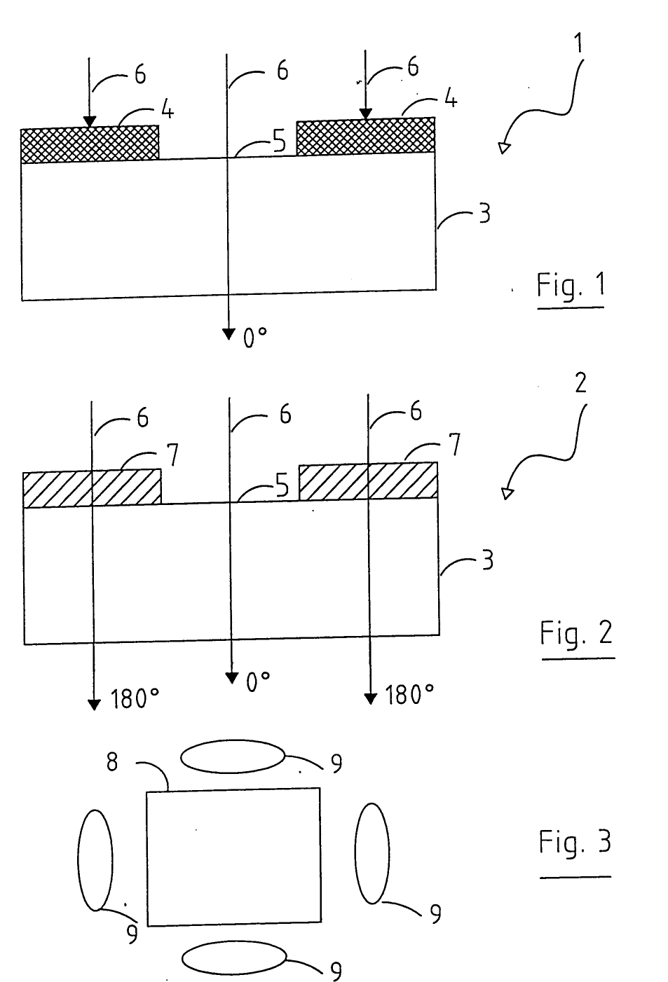

In FIG. 1 a binary type mask is illustrated schematically according to the known art.

According to what is illustrated in said figure, a conventional mask, also called binary, is indicated with 1.

Mask 1 is realised with a layer of transparent quartz 3 and an over-layer of opaque chrome 4 on which the opening of the etch window 5 is defined for the realisation of the contact, by means of an incident luminous source 6 on said etch window 5.

In addition it can be noted that said layer of chrome 4 does not permit the passage of the incident wave 6 while the etch window 5 enables it without leading to any change of phase in the incident luminous source 6.

FIG. 2 shows an attenuated phase shifting mask according to the known art.

Mask 2 is an attenuated phase shifting mask, also called Att.PSM, and uses a layer of partially transparent material 6 in place of said chrome layer 3.

Said layer 7 induces a phase shifting of 180° in the electric field of the incident wave 6.

In this type of mask use is made of the destructive interference between light coming from the clear zones 5, which define the circuit pattern that is required to be transferred onto the wafer, and the radiation transmitted from the partially transparent layer 7. This is used for defining contacts on the wafer which are smaller compared to those that can be obtained with a binary mask and through a good process window.

FIG. 3 illustrates a diffraction figure generated by a single square opening.

According to what is illustrated in said figure it can be noted that a contact 8 with a square shape, that results as the plan section of an Att.PSM mask adapted for the etching of the resist, is surrounded by a series of lobes 9.

Said lobes 9 are structures that are printed on the resin in proximity to the contact and this can cause inconveniences such as short circuits and degradation of the quality of the contacts.

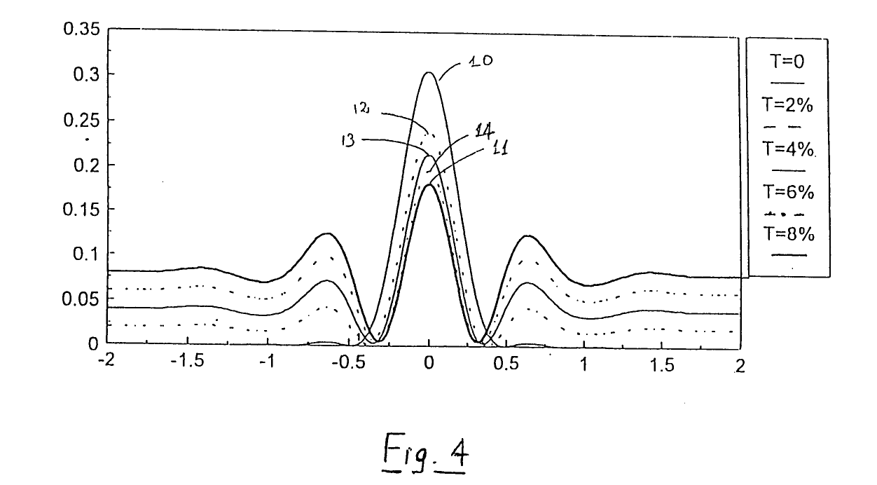

The cause of this effect is intrinsic to the technology of the Att.PSM mask and to the formation physics of the area image with which the resin deposited on the wafer is exposed. In fact, in the typical case of diffraction of Fraunhofer, the classic optics permit the definition of the course of the luminous intensity, that is of the area image, in function of the spatial position according to the equation : Y=(sin X)²/X², as illustrated in FIG. 4.

FIG. 4 shows a plurality of graphics of the transmission intensity in the case of Att.PSM-type masks.

As can be noted in FIG. 4, the masks of this type show a transmittance that is a damped oscillating function in accordance with the previously described function.

According to what is illustrated in said graph an axis of the x-coordinate indicating the dimension of the contact expressed in μm and an axis of the ordinates indicating normalised intensity can be noted.

As can be seen the side lobe results more accentuated in percentage at the increase of the transmittance T of the mask. In fact for a null transmittance (T=0%), that is a binary type mask like that shown in FIG. 1, represented with a continuous line graph 10, the side lobe effect is practically null, while for a mask having a transmittance in percentage equal to 8 (T=8%), that is a square-section Att.PSM mask, represented with a continuous bold line 11, the side lobe effect results accentuated.

In the figure there are also represented intermediate cases 12, for T=2% graphed with a dashed line, 13, for T=4% graphed with a continuous line, 14, for T=6% graphed with a line-dot line, between the two limits previously exposed.

To obtain larger depth of focus it is therefore necessary that the transmittance T is the highest possible, but as seen it brings a considerable increase of the “side lobe effect”.

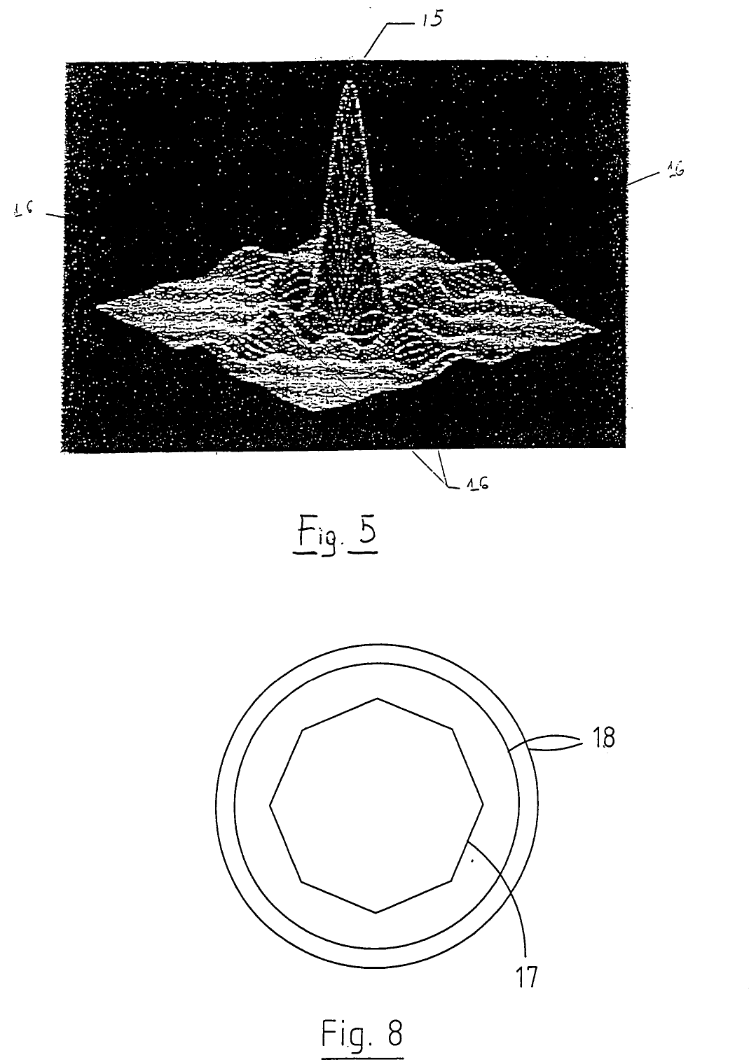

FIG. 5 illustrates a three-dimensional view of the side lobe effect in an Att.PSM-type mask.

According to what is illustrated in said figure it can be noted that with the use of said masks consideration must be taken of the side lobe effect, because if a zero-order maximum diffraction 15 is associated with a normalised transmission intensity of value 1, which defines the dimension of the contact, the result is obtained that the side lobe is given by the intensity corresponding to a one-order maximum diffraction 16 whose value results being equal to 0.047. Said one-order maximum is distributed around the contact following the two orthogonal directions, as previously illustrated schematically in FIG. 3.

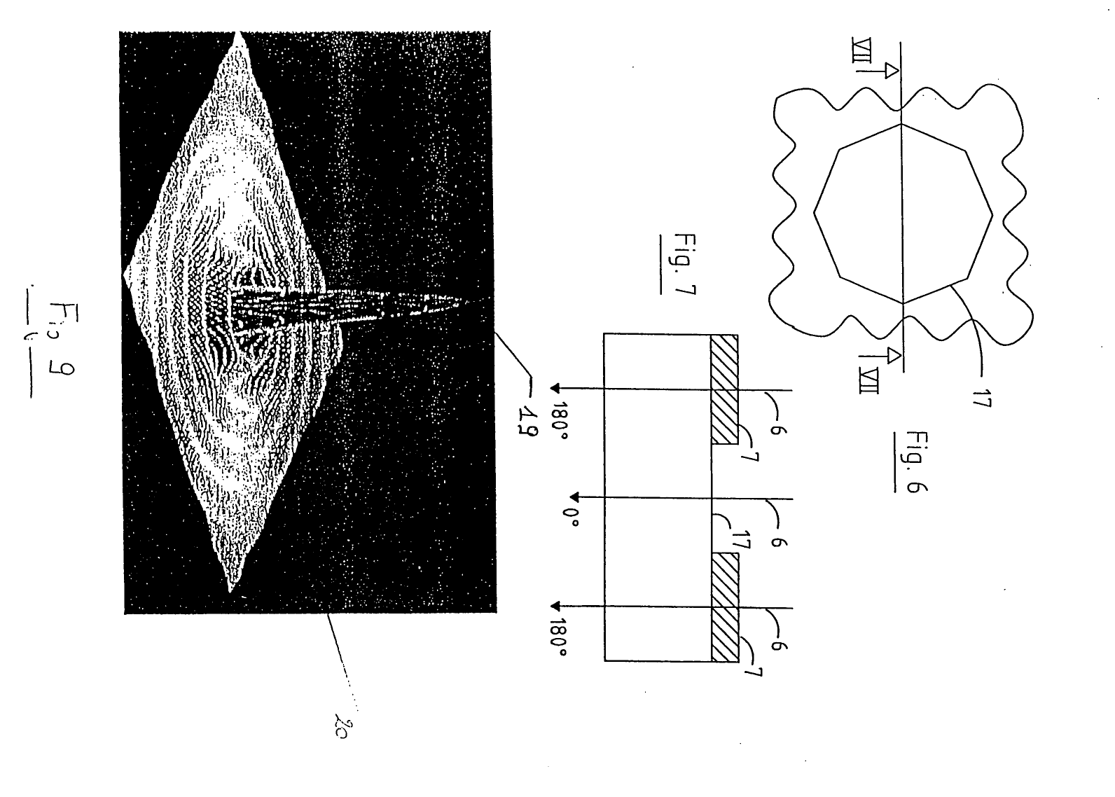

FIG. 6 shows a plan view of a portion of an Att.PSM mask according to the present invention.

According to what is illustrated in said figure it can be noted that the etch window has an octagonal section 17 capable of considerably reducing the side lobe effect, as shown below in FIGS. 8 and 9.

Using such a section the contacts are made as round as possible so that the disadvantages of the Att.PSM masks are considerably reduced, thus obtaining contacts which have better electric-geometric characteristics compared to the state of the technique.

FIG. 7 illustrates said mask according to the invention in section according to the VII-VII line of FIG. 6;

The structure of the mask with octagonal-section etch window as can be inferred from such figure, results being similar to the Att.PSM mask with square-section etch window shown in FIG. 2.

Therefore, adopting a polygonal section to make the contact, tangible improvements in the quality of the contact itself are obtained, but this section can also be applied every time a mask fit for the opening of several layers of a device has to be made. For example a mask with polygonal section can be used for the formation of the so-called trenches or for the via levels in a layer of polysilicon.

FIG. 8 shows a diffraction figure generated by a contact according to the invention.

Said drawing represents a diffraction figure generated by an octagonal-shaped contact 17. In this case the distribution of the side lobe around said contact 17 results as being more uniform and does not present privileged directions 18.

Thus having made an Att.PSM mask with an octagonal section permits undesired side lobe effects to be reduced on the wafer caused by phase shifting masks improving the intrinsic resolution and the depth of focus which can be obtained with this technology.

FIG. 9 illustrates a three-dimensional view of the side lobe effects in an Att.PSM-type mask according to the present invention.

In said figure a three-dimensional view of the luminous intensity is graphed approximating the octagon with a circumference through an equation of the type: Y=(2J₁(X))²/X² where J₁(X) indicates a function of Bessel of order 1.

The zero-order maximum diffraction 19 to which a normalised intensity of 1 is associated defines the dimension of the contact. The normalised intensity of the one-order maximum 20 gives the dimension of the side lobe effect which results being equal to 0.0175.

Said one-order maximum is distributed around the contact not having any privileged direction but extending uniformly around the contact produced on the surface of the wafer, as previously schematically illustrated in FIG. 6.

In this manner using the octagonal shape for the contact drawn on the reticle, the undesired side lobe effects are reduced for any type of contact whether it be dense or isolated.

The values of the focus depth and of the minimum resolution obtainable, therefore, with an attenuated phase shifting mask with square-section contacts, are increased by drawing on the mask contacts with an octagonal shape or in general with a circular shape.

Having thus described at least one illustrative embodiment of the invention, various alterations, modifications, and improvements will readily occur to those skilled in the art. Such alterations, modifications, and improvements are intended to be within the spirit and scope of the invention. Accordingly, the foregoing description is by way of example only and is not intended as limiting. The invention is limited only as defined in the following claims and the equivalents thereto.

What is claimed is:

1. An apparatus comprising:
a source of an incident electromagnetic wave;
a first plate of material transparent to the electromagnetic wave; and
a layer of phase shift material having defined therethrough a polygonal window with at least six sides.

2. The apparatus according to claim 1, wherein said layer is adapted to define features of a semiconductor device.

3. The apparatus according to claim 1, wherein said polygonal window is octagonal.

4. The apparatus according to claim 1, wherein said polygonal window has such a number of sides as to form an approximately circular shape.

5. The apparatus according to claim 1, wherein said layer of phase shift material causes a 180° phase shift of the incident electromagnetic wave.

6. The apparatus according to claim 1, wherein said layer of phase shift material at least partially absorbs the incident electromagnetic wave at the wavelength used.

7. A method of defining contacts on an integrated circuit device using an electromagnetic wave including:
providing an integrated circuit device substrate, a first plate of material transparent to the electromagnetic wave placed over the substrate, and a layer of phase shift material having defined therethrough a polygonal etch window with at least six sides; and
directing the electromagnetic wave at the substrate through the layer of phase shift material and first plate.

8. The method according to claim 7, wherein the layer causes a 180° phase shift of the electromagnetic wave.

9. The method according to claim 7, wherein the layer partially absorbs the electromagnetic wave.

10. An integrated circuit contact formed by directing an electromagnetic wave at a substrate through a first plate of material transparent to the electromagnetic wave placed over the substrate, and a layer of phase shift material placed over the first plate having defined therethrough a polygonal etch window with at least six sides.

11. The integrated circuit contact according to claim 10, formed by an octagonal window.

12. The integrated circuit contact according to claim 10, formed by a polygonal etch window having such a number of sides as to form an approximately circular shape.

13. The integrated circuit contact according to claim 12, wherein the layer of phase shift material causes a 180° phase shift of the photoelectric wave.

14. The integrated circuit contact according to claim 10, wherein the layer made of transparent material partially absorbs the photoelectric wave.
